(19) United States
(12) Patent Application Publication
(10) Pub. No.: US 2024/0153123 A1
(43) Pub. Date: May 9, 2024

(54) Isogeometric Analysis Method Based on a Geometric Reconstruction Model

(71) Applicant: SOUTH CHINA UNIVERSITY OF TECHNOLOGY, Guangzhou City (CN)

(72) Inventors: Yingjun WANG, Guangzhou City (CN); Jinghui LI, Guangzhou City (CN); Zhencong LI, Guangzhou City (CN); Jiancheng ZHANG, Guangzhou City (CN); Nan WANG, Guangzhou City (CN)

(21) Appl. No.: 17/773,169

(22) PCT Filed: Nov. 24, 2020
(86) PCT No.: PCT/CN2020/131070

§ 371 Date: Apr. 29, 2022

(30) Foreign Application Priority Data
Apr. 7, 2020 (CN) 202010263526.4

(51) Int. Cl. G06T 7/60; G06F 30/10; G06T 7/12; G06T 17/00

(52) U.S. Cl. CPC G06T 7/60; G06F 30/10; G06T 7/12; G06T 17/00; G06T 2207/10028; G06T 2210/21; G06T 2210/56

(57) ABSTRACT

The present invention discloses an isogeometric analysis method based on a geometric reconstruction model comprising steps of: dividing boundaries of a CAD model into triangular patches or directly based on point cloud data, generating a closed regular embedded domain, dividing the embedded domain into regular sub-domains, dividing the elements according to a positional relationship between the boundaries of the triangular patches/points and the elements into trimmed elements and untrimmed elements; calculating a minimum directional distance from each vertex of a trimmed element to a triangular patch near the trimmed element; using the minimum directional distance to divide the untrimmed elements into real and virtual elements; using the minimum directional distance as a level set function value, and using a marching tetrahedra algorithm to reconstruct a displayed geometric model based on the regular embedded domain; after obtaining the level set function value, calculating the level set function value of a Gaussian point in an element, if the value is greater than or equal to zero, the Gaussian point is in a real domain; if the value is less than zero, the Gaussian point is outside the real domain. The present invention can be directly used to analyze complex models with arbitrary geometric shapes, and can also be used to analyze point cloud models from reverse engineering and voxel models from image data. The present invention may be directly used to analyze complex models with arbitrary geometric shapes, and may also be used to analyze point cloud models from reverse engineering and voxel models from image data.

### TECHNICAL FIELD

The invention relates to the technical field of three-dimensional model reconstruction, in particular to an isogeometric analysis method based on a geometric reconstruction model.

### TECHNICAL BACKGROUND

The isogeometric analysis method was proposed by Hughes. It uses the basis function for geometric model and computer model to complete computer-aided design and engineering analysis, which has become an efficient digital analysis method. As it uses the same basis functions as CAD, isogeometric analysis is an efficient method for building CAD models and engineering analysis. In addition, the isogeometric analysis method has the advantages of low computer power consumption and high accuracy. As a result, isogeometric analysis is widely used in various models and engineering analysis. However, CAD's boundary representation and tensor product curve and surface structure make isogeometric analysis of three-dimensional complex geometric models very difficult. The most important part of isogeometric analysis is to obtain a parametric model of a spline model of a model. In practical applications, it is impossible for a complex analysis model to be represented by a spline model in the form of a complete tensor product, which makes isogeometric analysis not directly applicable to engineering models with complex topological structures. In addition, CAD systems usually use boundary representation methods to represent geometric objects. There are no three-dimensional splines for three-dimensional problems in CAD systems. In order to solve the above-mentioned problems and the existing problems in engineering analysis, a method that may represent a complex geometric model based on boundary polygons or point cloud, and a method that may realize geometric analysis based on the model representation is needed.

### SUMMARY OF THE INVENTION

The purpose of the present invention is to overcome shortcomings of the current technology and to provide an isogeometric analysis method based on a geometric reconstruction model.

The purpose of the present invention may be achieved through the following technical solutions:

An isogeometric analysis method based on a geometric reconstruction model, comprising steps of:
dividing boundaries of aCAD model into triangular patches, generating a closed regular embedded domain based on boundaries of the triangular patches,
dividing the embedded domain into regular sub-domains, namely elements; for a point cloud, building an embedded domain may be based on points;
dividing the elements according to a positional relationship between the boundaries of the triangular patches/points and the elements into two categories: elements with a patch boundary/a point inside (trimmed elements) and elements without a patch boundary/a point (untrimmed elements);
calculating a minimum directional distance from each vertex of a trimmed element to a triangular patch near the trimmed element;
after obtaining the minimum directional distance, using the directional distance to divide the untrimmed elements into real and virtual elements;
using the minimum directional distance as a level set function value, and using a marching tetrahedra algorithm to reconstruct a displayed geometric model based on the regular embedded domain;
after obtaining the level set function value, calculating the level set function value of a Gaussian point in an element, if the value is greater than or equal to zero, the Gaussian point is in a real domain; if the value is less than zero, the Gaussian point is outside the real domain. Only Gaussian points in the real domain are needed to calculate the element stiffness matrix.

Further, in the steps of dividing boundaries of a CAD model into triangular patches, generating a closed embedded domain based on boundaries of the triangular patches, dividing the embedded domain into regular sub-domains, the size of the elements is larger than the size of the triangular patches.

Further, a method of generating a closed regular embedded domain based on the boundaries of the triangular patches is: constructing a regular rectangular parallelepiped bounding box with a size of (Xₘₐₓ-Xₘᵢₙ)×(Yₘₐₓ-Yₘᵢₙ)×(Zₘₐₓ-Zₘᵢₙ) to contain all the triangular patches, through maximum and minimum values of vertices of all triangular patches on the coordinate axis, namely Xₘₐₓ, Xₘᵢₙ, Yₘₐₓ, Yₘᵢₙ, Zₘₐₓ, Zₘᵢₙ. The space occupied by the bounding box is the embedded domain.

For a point cloud model, after directly obtaining maximum and minimum values of each point in the point cloud on the coordinate axis, the same method is used to construct the embedded domain.

Further, in the steps of dividing the elements into two categories according to a positional relationship between patch boundaries and the elements, the elements are divided according to the following: if a element contains any vertex or center of a triangular boundary patch, the element is an element with a boundary patch inside (trimmed elements); otherwise, it is an element without a boundary patch (untrimmed elements). For a element constructed by a point cloud, dividing an embedded domain, if the element contains any point, the element is an element with an internal point; otherwise (trimmed elements), it is an element without a point (untrimmed elements).

Further, in the step of calculating the minimum directional distance from each vertex of a trimmed element to a triangular patch near the trimmed element, finding a point on each triangular boundary patch in sequence with a closest distance to a vertex P of an element, calculating a distance from the point to the point P, selecting a minimum value to obtain a minimum distance, determining a positive direction of the minimum distance as a direction from a vertex to the triangular boundary patch, converting the minimum distance into a directional distance according to a relationship between the direction of the minimum distance and a direction of an exterior vector of the triangular patch.

For the point cloud, calculating a distance from a vertex of a trimmed element to a point and selecting a minimum distance. The outer normal of the point cloud may be obtained by a 3D scanner. According to the direction from the vertex to the nearest point and an exterior vector of the point, the minimum distance may be converted into a directional distance.

Further, after obtaining a minimum directional distance of a vertex of a trimmed element, the untrimmed elements are divided into real elements and virtual elements by using the directional distance, and the dividing method is as follows: starting from an adjacent untrimmed element of a trimmed element, if the untrimmed element contains vertices with a positive minimum directional distance, then the untrimmed element is a real element; if the untrimmed element contains vertices with a negative minimum directional distance, the untrimmed element is a virtual element; in this way, using classified untrimmed elements to expand layer by layer to other unclassified untrimmed elements, until all the untrimmed elements are classified.

Further, the method of expanding layer by layer the unclassified untrimmed elements is: expanding untrimmed elements shared by vertices of a trimmed element, and then expanding other untrimmed elements in turn, a principle of expansion is: if a minimum directional distance of any vertex of a untrimmed element is a negative value, then minimum directional distances of all vertices of the untrimmed element are set to the negative value, and the untrimmed element is a virtual element(that is, the element is located outside the boundary of the embedded model); if a minimum directional distance of any vertex of the untrimmed element is a positive value, then the minimum directional distances of all vertices of the untrimmed element are set to the positive value, and the untrimmed element is a real element(that is, the element is located insideboundary of the embedded model).

Further, in the step of reconstructing the geometric model, subdividing a trimmed element into six tetrahedrons, at this time, a directional distance of each vertex of the tetrahedrons is known, for a tetrahedron with minimum directional distances of its vertices having both positive and negative values, using a linear interpolation to calculate an intersection point where the minimum directional distance on each side of the tetrahedron is zero, connecting intersections to form a plane with a directional distance of zero. Constructing a zero plane according to the above method for all the elements, and combining them to obtain a reconstructed geometric model. This reconstructed model may be used for model manufacturing.

Further, characterized in that, in the step of, after obtaining the level set function value, calculating the level set function value of a Gaussian point in an element, a Gaussian point with a level set value greater than zero is reserved for calculating an element stiffness matrix, and a Gaussian point with a level set value less than zero is removed and does not participate in a calculation of the stiffness matrix.

Compared with the current technology, the present invention has the following beneficial effects:
1. The present invention is based on a level set function implicit approximation reconstruction model, which may quickly identify an element type in an embedded domain without cumbersome CAD intersection technology.
2. The invention solves the technical bottleneck that the existing isogeometric analysis is difficult to directly analyze the complex geometric model, by embedding the geometric model into a regular embedded domain that may be directly expressed by a CAD spline function, and that an isogeometric analysis may be directly realized by reconstructing the model.
3. The present invention may directly perform isogeometric analysis on a point cloud model without a need to reconstruct a geometric model based on a point cloud display.

### DESCRIPTION OF FIGURES

FIG. 1 is an illustrative diagram of a discrete boundary representation method for obtaining a design model in the present invention.

FIG. 2 is an illustrative diagram of a method of dividing elements into elements with boundary patch and elements without boundary patch in the present invention.

FIG. 3 is an illustrative diagram of an expansion of real and virtual elements in the present invention.

FIG. 4 is an illustrative diagram of a method for obtaining directional distance in the present invention.

FIG. 5 is an illustrative diagram of a marching tetrahedra algorithm in the present invention.

FIG. 6 is an illustrative diagram of a method for judging whether a Gaussian point is in the real domain in the present invention.

### DESCRIPTION

Hereinafter, the present invention will be further described in detail with reference to the embodiments and the figures, but the embodiments of the present invention are not limited thereto.

### Embodiments

In this embodiment, an isogeometric analysis method based on a geometric reconstruction model is provided, which comprises the steps of:

S1. dividing boundaries of a CAD model into triangular patches, generating a closed embedded domain based on boundaries of the triangular patches, dividing the embedded domain into regular sub-domains, namely elements; for a point cloud, building an embedded domain may be based on points. The regular elements are rectangular parallelepipeds of the same size.

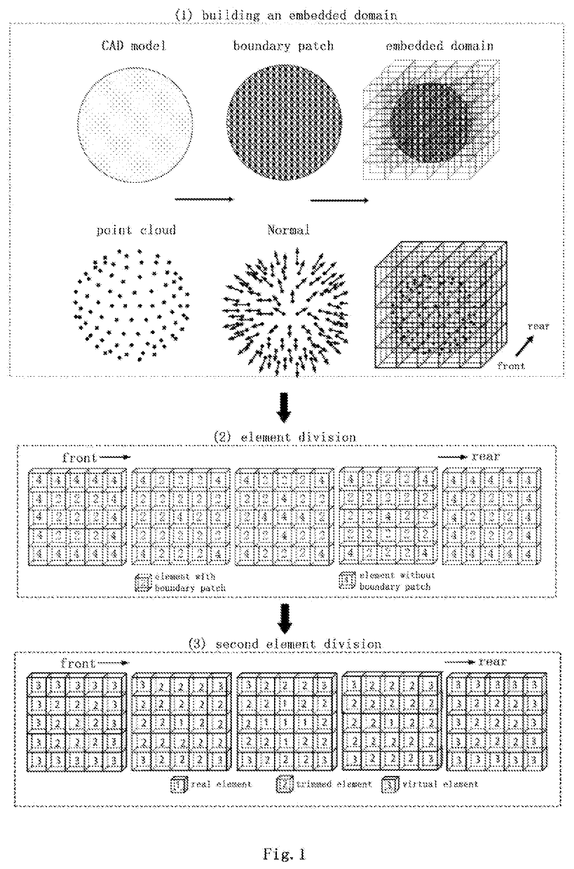

FIG. 1 is an illustrative diagram of obtaining a discrete boundary representation of a design model and a point cloud model. Specifically, the embedded domain is constructed according to a computer-aided design CAD model or a point cloud, and the embedded domain is divided into regular sub-domains, namely elements.

S2. dividing the elements into two categories according to a positional relationship between the boundaries of the patches/points and the elements: elements with a patch boundary/a point inside (trimmed elements) and elements without a patch boundary/a point;

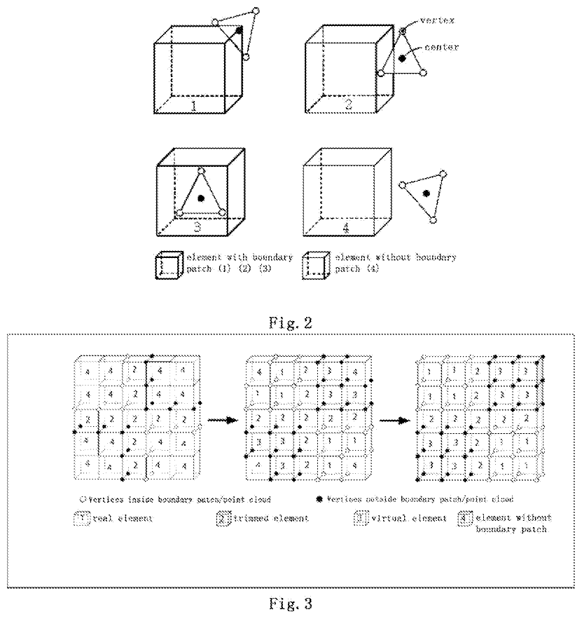

FIG. 2 shows an illustrative diagram of element division into elements with patch boundary and elements without patch boundary. The initial element division is based on the following: if an element contains any triangular patch vertex or center, then the element is an element with a patch boundary inside, otherwise, it is an element without a patch boundary.

S3. calculating a minimum directional distance from each vertex of a trimmed element to a triangular patch near the trimmed element.

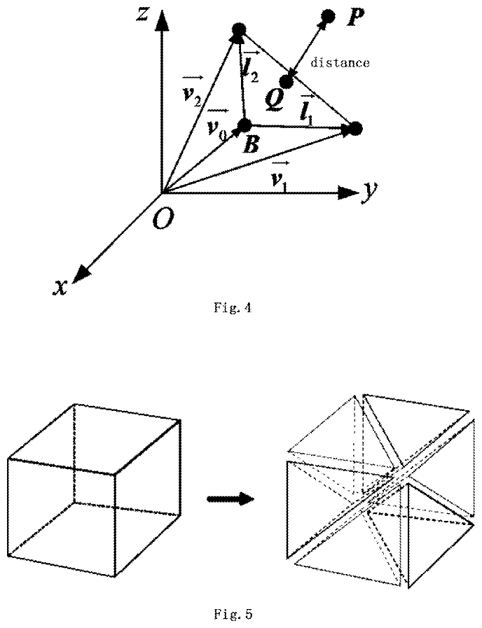

FIG. 4 shows an illustrative diagram of finding directional distances. A parameterized expression formula of a triangular patch is:

T(s,t)=B+sl₁+tl₂(s,t)∈D={(s,t):≥0,t≥0,s+t≤1}

where B represents a vertex of a triangle, l₁ and l₂ are vectors corresponding to two sides of the triangle with B as a vertex, s and t are corresponding parameter values, which are between 0 and 1, any set of s and t parameter values corresponds to a point in an area of the triangle.

A closest point on the triangular boundary patch to each vertex P of an element is found to calculate the minimum directional distance.

A formula for calculating a distance from a vertex P of an element to any point Q on a triangular boundary patch(the positional parameters in the triangles are sand t) is as follows:

Dis(s,t)=|Q−P|=\sqrt{as²+2bst+ct²+2ds+2et+f}

f=(B−P)·(B−P)

a=l₁·l₁,b=l₁·l₂,c=l₂·l₂,d=l₁·(B−P),e=l₂(B−P)

wherein s and t represent position parameter coordinates of point Q, B−P represents a vector from point P to point B, and l₁ and l₂ are vectors corresponding to two sides of the triangle with B as the vertex. The other parameters a, b, c, d, e are defined by formulas.

Taking a vertex of an element as the starting point, and a minimum distance point on the triangular boundary patch as the end point, a vector may be defined. The angle between this vector and the outer normal direction of the triangular element is less than or equal to 90 degrees, the distance is positive. If the angle is greater than 90 degrees, the distance is negative, so the minimum distance is converted to a minimum directional distance. For a trimmed element, the minimum directional distance of some vertices must be greater than zero, and the minimum directional distance of some vertices must be less than zero.

S4. after obtaining the directional distance, using the directional distance to divide the other untrimmed elements into real and virtual elements.

After the minimum directional distance of a vertex of a trimmed element is obtained, the untrimmed elements are divided into real elements and virtual elements by using the directional distance, and the dividing method is: starting from an adjacent untrimmed element of a trimmed element, if the untrimmed element contains vertices with a positive minimum directional distance, the untrimmed element is a real element; if the untrimmed element contains vertices with a negative minimum directional distance, the untrimmed element is a virtual element; in this way, using classified untrimmed elements to expand layer by layer to other unclassified untrimmed elements, until all the untrimmed elements are classified.

FIG. 3 shows an illustrative diagram of an expansion of real and virtual elements. First, expand the untrimmed element shared by the vertices of the trimmed element, then expanding other untrimmed elements in turn, a principle of expansion is: if a minimum directional distance of any vertex of an untrimmed element is a negative value, then minimum directional distances of all vertices of the untrimmed element are set to the negative value, and the untrimmed element is a virtual element(that is, the element is located outside the boundary of the embedded model); if a minimum directional distance of any vertex of the untrimmed element is a positive value, then the minimum directional distances of all vertices of the untrimmed element are set to the positive value, and the untrimmed element is a real element (that is, the element is located inside the boundary of the embedded model).

S5. using the directional distance as a level set function value, and using a marching tetrahedra algorithm to reconstruct a displayed geometric model based on the regular embedded domain, for processing and manufacturing.

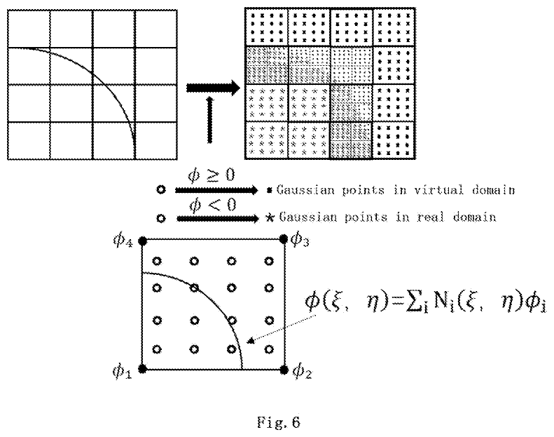

FIG. 5 shows an illustrative diagram of a marching tetrahedra algorithm. A trimmed element is divided into six tetrahedrons, and a linear interpolation is used to calculate a plane in the tetrahedron whose vertices are all zero in directional distance, and a model may be reconstructed based on this plane.

Wherein the linear interpolation method to calculate the directed distance is as follows:

$$\\ {x}_{0} = \frac{{d}_{2}}{{d}_{2} - {d}_{1}} {x}_{1} - \frac{{d}_{1}}{{d}_{2} - {d}_{1}} {x}_{2}$$

Wherein d₁ and d₂ are directional distances of two ends of the side length of a tetrahedron, and x₁ and x₂ are the coordinates of the two ends.

S6. after obtaining the level set function value, calculating the level set function value of a Gaussian point of an element, if the value is greater than or equal to zero, the Gaussian point is in a real domain; if the value is less than zero, the Gaussian point is outside the real domain. Only Gaussian points in the real domain are needed to calculate the element stiffness matrix.

FIG. 6 shows an illustrative diagram of judging whether a Gaussian point is in the real domain. Generally, the stiffness matrix of an untrimmed element is the accumulation of values at all Gaussian points in the element. For the trimmed element, only the values at the Gaussian points whose level set value is greater than zero are selected for accumulation.

A method for calculating the level set function value of the Gaussian point is as follows:

$$\\ ϕ ( ξ , η , ζ ) = {\sum }_{i} {N}_{i} ( ξ , η , ζ ) {ϕ}_{i}$$

Wherein(ξ, η, ζ) are coordinates of the Gaussian point of the level set function, Nᵢ and ϕᵢ are shape functions and level set function values of i vertices of an embedded domain element.

The above-mentioned embodiments are preferred embodiments of the present invention, but the embodiments of the present invention are not limited by the above-mentioned embodiments, and any other changes, modifications, substitutions, combinations, simplifications made without departing from the spirit and principle of the present invention, all should be equivalent replacement methods, and they are all included in the protection scope of the present invention.

1. An isogeometric analysis method based on a geometric reconstruction model, characterized in that, comprising steps of:
dividing boundaries of aCAD model into triangular patches, generating a closed regular embedded domain based on boundaries of the triangular patches, dividing the embedded domain into regular sub-domains, namely elements; for a point cloud, building an embedded domain based on points;
dividing the elements into two categories according to a positional relationship between the boundaries of the triangular patches/points and the elements: elements with a patch boundary/a point inside, namely trimmed elements, and elements without a patch boundary/a point, namely untrimmed elements;
calculating a minimum directional distance from each vertex of a trimmed element to a triangular patch near the trimmed element;
after obtaining the minimum directional distance, using the directional distance to divide the untrimmed elements into real and virtual elements;
using the minimum directional distance as a level set function value, and using a marching tetrahedra algorithm to reconstruct a displayed geometric model based on the regular embedded domain;
after obtaining the level set function value, calculating the level set function value of a Gaussian point in an element, if the value is greater than or equal to zero, the Gaussian point is in a real domain; if the value is less than zero, the Gaussian point is outside the real domain.

2. The method according to claim 1, characterized in that, in the steps of dividing boundaries of a CAD model into triangular patches, generating a closed regular embedded domain comprising the boundary model based on boundaries of the triangular patches, dividing the embedded domain into regular sub-domains, the size of the elements is larger than the size of the triangular boundary patches.

3. The method according to claim 1, characterized in that, in the steps of dividing the elements into two categories according to a positional relationship between boundary patches and the elements, the elements are divided according to the following: if an element contains any vertex or center of a triangular patch, the element is an element with a boundary patch inside; otherwise, it is an element without a boundary patch;
for an element constructed by a point cloud, dividing an embedded domain, if the element contains any point, the element is an element with an point inside; otherwise, it is an element without a point.

4. The method according to claim 1, characterized in that, in the step of calculating the minimum directional distance from each vertex of a trimmed element to a triangular patch near the trimmed element, finding a point on the triangular patch with a closest distance to a point P, calculating a distance from a point of a space to the triangle, selecting a minimum value to obtain a minimum distance, determining a positive direction of the minimum distance as a direction from a vertex to the triangular patch, converting the minimum distance into a directional distance according to a relationship between a direction of the minimum distance and a direction of the outer normal vector of the triangular patch,
for the point cloud, calculating a distance from a vertex of a trimmed element to a point and selecting a minimum distance, and then converting the minimum distance into a directional distance according to a direction from the vertex to a nearest point and an exterior vector of the point.

5. The method according to claim 4, characterized in that, a parameterized expression formula of a triangular patch is:
T(s,t)=B+sl₁+tl₂(s,t)∈D={(s,t):s≥0,t≥0,s+t≤1}
where B represents a vertex of a triangle, l₁ and l₂ are vectors corresponding to two sides of the triangle with B as a vertex, s and t are corresponding parameter values, which are between 0 and 1, any set of s and t parameter values corresponds to a point in an area of the triangle;
a formula for calculating a distance from a vertex P of an element to any point Q on a triangular patch is as follows:
Dis(s,t)=|Q−P|=\sqrt{as²+2bst+ct²+2ds+2et+f}
f=(B−P)·(B−P)
a=l₁·l₁,b=l₁·l₂,c=l₂·l₂,d=l₁·(B−P),e=l₂·(B−P)
wherein s and t represent position parameter coordinates of point Q, B−P represents a vector from point P to point B, and l₁ and l₂ are vectors corresponding to two sides of the triangle with B as the vertex. The other parameters a, b, c, d, e are defined by formulas.

6. The method according to claim 1, characterized in that, in the steps of, after obtaining the directional distance, using the directional distance to divide the untrimmed elements into real and virtual elements, starting from an adjacent untrimmed element of a trimmed element, if the untrimmed element contains vertices with a positive minimum directional distance, the untrimmed element is a real element; if the untrimmed element contains vertices with a negative minimum directional distance, the untrimmed element is a virtual element; in this way, using classified untrimmed elements to expand layer by layer to other unclassified untrimmed elements, until all the untrimmed elements are classified.

7. The method according to claim 6, characterized in that, the method of expanding layer by layer the unclassified untrimmed elements is: expanding untrimmed elements shared by vertices of a trimmed element, and then expanding other untrimmed elements in turn, a principle of expansion is: if a minimum directional distance of any vertex of a untrimmed element is a negative value, then minimum directional distances of all vertices of the untrimmed element are set to the negative value, and the untrimmed element is a virtual element; if a minimum directional distance of any vertex of the untrimmed element is a positive value, then the minimum directional distances of all vertices of the untrimmed element are set to the positive value, and the untrimmed element is a real element.

8. The method according to claim 1, characterized in that, in the step of reconstructing the geometric model, the reconstruction method is: subdividing a trimmed element into six tetrahedrons, at this time, a directional distance of each vertex of the tetrahedrons is known, for a tetrahedron with minimum directional distances of its vertices having both positive and negative values, using a linear interpolation to calculate an intersection point where the minimum directional distance on each side of the tetrahedron is zero, connecting intersections to form a plane with a directional distance of zero; constructing a zero plane according to the above method for all the elements, and combining them to obtain a reconstructed geometric model.

9. The method according to claim 1, characterized in that, in the step of, after obtaining the level set function value, calculating the level set function value of a Gaussian point in a element, a Gaussian point with a level set value greater than zero is reserved for calculating an element stiffness matrix, and a Gaussian point with a level set value less than zero is removed and does not participate in a calculation of the stiffness matrix.

10. The method according to claim 1, characterized in that, a method for calculating the level set function value of the Gaussian point is as follows:
$$\\ ϕ ( ξ , η , ζ ) = {\sum }_{i} {N}_{i} ( ξ , η , ζ ) {ϕ}_{i}$$
wherein (ξ, η, ζ) are coordinates of the Gaussian point of the level set function, Nᵢ and ϕᵢ are shape functions and level set function values of i vertices of an embedded domain element.
